(19) United States
(12) Patent Application Publication
(10) Pub. No.: US 2006/0201428 A1
(43) Pub. Date: Sep. 14, 2006

(54) Shower head and method of fabricating the same

(76) Inventors: Young Hoon Park, Pyungtaek-city (KR); Keun Jae Yoo, Pyungtaek-city (KR); Hong Joo Lim, Pyungtaek-city (KR); Sang Jin Lee, Pyungtaek-city (KR); Ik Haeng Lee, Pyungtaek-city (KR); Sang Kyu Lee, Pyungtaek-city (KR); Hyun Soo Kyung, Pyungtaek-city (KR); Jang Ho Bae, Pyungtaek-city (KR)

Correspondence Address: CANTOR COLBURN, LLP, 55 GRIFFIN ROAD SOUTH, BLOOMFIELD, CT, 06002, US

(21) Appl. No.: 11/436,473

(22) Filed: May 18, 2006

Related U.S. Application Data
(63) Continuation-in-part of application No. 10/484,047, filed on May 10, 2004.

(30) Foreign Application Priority Data
Jul. 19, 2001 (KR) 10-2001-0043496

(51) Int. Cl. C23F 1/00; C23C 16/00

(52) U.S. Cl. 118/715; 156/345.34

(57) ABSTRACT

Provided is a shower head used in a reactor for thin film deposition, and a method of fabricating the shower head. The shower head for injecting gases onto a wafer mounted on a wafer block includes: a first supply path supplying a first reaction gas and a second supply path supplying a second reaction gas; a first main path connected to the first supply path and in the plane of the shower head, a plurality of first sub-paths diverging from the first main path in the plane of the shower head, a plurality of first diffuse holes formed regularly spaced on a bottom surface of the shower head, and a plurality of first diffuse paths connecting the plurality of first sub-paths to the plurality of first diffuse holes; a second main path connected to the second supply path in the plane of the shower head and not contacting the first main path, a plurality of second sub-paths diverging from the second main path in the plane of the shower head, a plurality of second diffuse holes formed regularly spaced on a bottom surface of the shower head, and a plurality of second diffuse paths connecting the plurality of second sub-paths and the plurality of second diffuse holes; and a sealing unit sealing open ends of the first and second main paths and open ends of the first and second sub-paths formed in the shower head.

### CROSS-REFERENCE TO RELATED PATENT APPLICATIONS

This application claims the benefit of Korean Patent Application No. 10-2001-0043496, filed on Jul. 19, 2001, in the Korean Intellectual Property Office, the disclosure of which is incorporated herein in its entirety by reference.

### BACKGROUND OF THE INVENTION

1. Field of the Invention

The present invention relates to a shower head used in a reactor for the deposition of a thin film on a wafer and a method of fabricating the shower head.

2. Description of the Related Art

A reactor for the deposition of thin films is an apparatus for forming thin films on a wafer arranged in the reactor by using a variety of reactant gases.

Deposition of high-purity thin films having good electrical properties on a wafer is necessary to form high-density chips. Recently, efforts have shifted from conventional chemical vapor deposition toward using atomic layer deposition (ALD) and thus there is an increased demand for efficient ALD processes and equipment for the manufacture of semiconductor devices. This is because the ALD technique should provide a deposited thin film of high quality and reliability even for more demanding designs, which are becoming more common in developing new technology in the semiconductor field.

### SUMMARY OF THE INVENTION

The present invention provides a shower head used in a reactor for effectively depositing a high-purity, thin film having good electrical characteristics and step-coverage on a wafer using a plurality of reactant gases and a method for fabricating the shower head.

According to an aspect of the present invention, there is provided a shower head injecting gases onto a wafer mounted on a wafer block, the shower head including: a first supply path supplying a first reaction gas and a second supply path supplying a second reaction gas; a first main path connected to the first supply path in the plane of the shower head, a plurality of first sub-paths diverging from the first main path in the plane of the shower head, a plurality of first diffuse holes formed regularly spaced on a bottom surface of the shower head, and a plurality of first diffuse paths connecting the plurality of first sub-paths to the plurality of first diffuse holes; a second main path connected to the second supply path in the plane of the shower head and not contacting the first main path, a plurality of second sub-paths diverging from the second main path in the plane of the shower head, a plurality of second diffuse holes formed regularly spaced on a bottom surface of the shower head, and a plurality of second diffuse paths connecting the plurality of second sub-paths to the plurality of second diffuse holes; and a sealing unit sealing open ends of the first and second main paths and open ends of the first and second sub-paths formed in the shower head.

The sealing unit may include a first main sealing member inserted into the open end of the first main path, and a first sub-sealing member inserted into the open end of the first sub-path.

A boundary between the open end of the first main path and the first main sealing member may be sealed by welding, and a boundary between the open end of the first sub-path and the first sub-sealing member may be sealed by welding.

The sealing unit may include a second main sealing member inserted into the open end of the second main path, and a second sub-sealing member inserted into the open end of the second sub-path.

A boundary between the open end of the second main path and the second main sealing member may be sealed by welding, and a boundary between the open end of the second sub-path and the second sub-sealing member may be sealed by welding.

The sealing unit may include a first rim member that is fitted around a lower side circumference of the shower head in order to cover the open ends of the first main path and the first sub-path.

A boundary between the lower side circumference of the shower head and the first rim member may be welded to seal the open ends of the first main path and the first sub-path.

The first main path and the second main path may be formed in the same direction as each other, or perpendicular to each other.

The first sub-path may be perpendicular to the first main path.

The second sub-path may be perpendicular to the second main path.

The first diffusion path may directly connect the first sub-path to the first diffuse hole.

The first diffuse path may be perpendicular to the first sub-path and the first diffuse hole.

The second diffusion path may directly connect the second sub-path to the second diffuse hole.

The second diffuse path may be perpendicular to the second sub-path and the second diffuse hole.

According to another aspect of the present invention, there is provided a method of fabricating a shower head for injecting the gas onto a wafer mounted on a wafer block, which includes a first supply path supplying a first reaction gas and a second supply path supplying a second reaction gas, the method including: forming a first main path penetrating a side of the shower head to be connected to the first supply path, a plurality of first sub-paths penetrating another side of the shower head to be connected to the first main path and diverging from the first main path in the plane of the shower head, and a plurality of first diffuse paths connecting the first sub-paths to the bottom surface of the shower head; forming a second main path penetrating the other side of the shower head at a different height from the first main path to be connected to the second supply path, a plurality of second sub-paths penetrating another side of the shower head to be connected to the second main path and diverging from the second main path in the plane of the shower head, and a plurality of second diffuse paths connecting the second sub-paths to the bottom surface of the shower head; and sealing open ends of the first and second main paths and open ends of the first and second sub-paths formed in the shower head.

The sealing of the open ends may further include sealing the open end of the first main path by inserting a first main sealing member into the open end of the first main path, and sealing the open end of the first sub-path by inserting a first sub-sealing member into the open end of the first sub-path.

A boundary between the open end of the first main path and the first main sealing member may be sealed by welding, and a boundary between the open end of the first sub-path and the first sub-sealing member may be sealed by welding.

The sealing of the open ends may further include sealing the open end of the second main path by inserting a second main sealing member into the open end of the second main path, and sealing the open end of the second sub-path by inserting a second sub-sealing member into the open end of the second sub-path.

A boundary between the open end of the second main path and the second main sealing member may be sealed by welding, and a boundary between the open end of the second sub-path and the second sub-sealing member may be sealed by welding.

The sealing of the open ends may include sealing the open ends of the first main path and the first sub-path by fitting a first rim member around a lower side circumference of the shower head.

A boundary between the lower side circumference of the shower head and the first rim member may be welded to seal the open ends of the first main path and the first sub-path.

The sealing of the open ends may include sealing the open ends of the second main path and the second sub-path by fitting a second rim member around an upper side circumference of the shower head.

A boundary between the upper side circumference of the shower head and the second rim member may be welded to seal the open ends of the second main path and the second sub-path.

The first sub-paths may be perpendicular to the first main path.

The second sub-paths may be perpendicular to the second main path.

The first and second main paths, the first and second sub-paths, and the first and second diffuse paths may be formed using a drilling method.

### BRIEF DESCRIPTION OF THE DRAWINGS

The above and other features and advantages of the present invention will become more apparent by describing in detail exemplary embodiments thereof with reference to the attached drawings in which:

FIG. 1 is cross-sectional view of a reactor for thin film deposition including a shower head according to an embodiment of the present invention;

FIG. 2 is a perspective view of the shower head of FIG. 1;

FIG. 3 is a bottom view of the shower head of FIG. 2;

FIG. 4 is a partially cut-away perspective view of the shower head of FIG. 1, showing a first main path connected to a first supply path and first diffuse holes;

FIG. 5 is a cross-sectional view of the shower head taken along line V-V of FIG. 4;

FIG. 6 is a side cut-away view showing the inside of the shower head of FIG. 5;

FIG. 7 is a partially cut-away perspective view of the shower head of FIG. 1, showing a second main path connected to a second supply path and second diffuse holes;

FIG. 8 is a cross-sectional view of the shower head taken along line VIII-VIII of FIG. 7;

FIG. 9 is a side cut-away view of the shower head of FIG. 8;

FIG. 10 is a partially cut-away perspective view of the shower head of FIG. 1, showing the first and second main paths connected to the first and second supply paths and the first and second diffuse holes;

FIG. 11 is an exploded perspective view of a shower head and a first and second rim members according to another embodiment of the present invention; and

FIG. 12 is a perspective view of the shower head of FIG. 11, to which the first and second rim members are coupled.

### DETAILED DESCRIPTION OF THE INVENTION

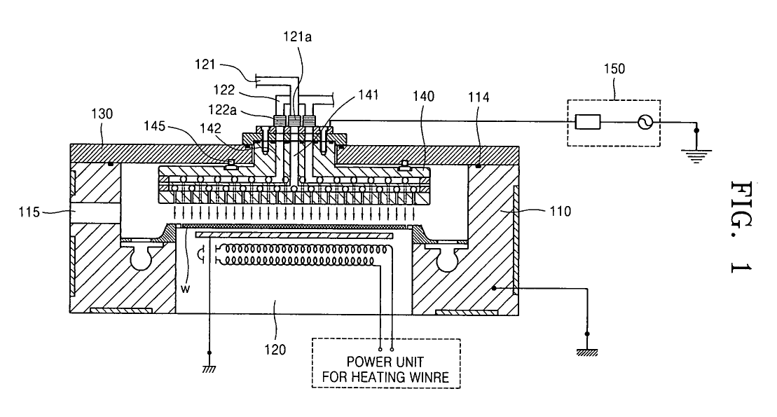

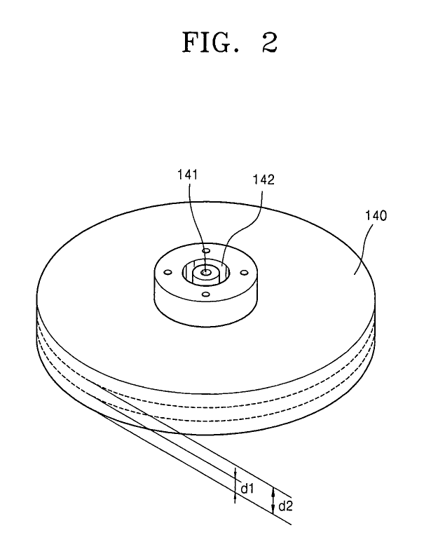

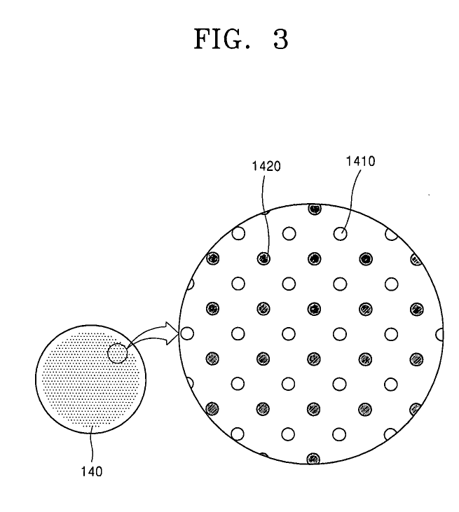

FIG. 1 is a cross-sectional view of a reactor for thin film deposition including a shower head according to an embodiment of the present invention, FIG. 2 is a perspective view of the shower head of FIG. 1, and FIG. 3 is a bottom view of the shower head of FIG. 2.

The reactor for thin film deposition including the shower head according to the present invention will be described as follows.

Referring to FIG. 1, the reactor for thin film deposition including the shower head according to an embodiment of the present invention includes a reactor block 110 which can contain a wafer w that is transferred through a wafer transfer slit 11 5, a wafer block 120 (see FIG. 3) installed in the reactor block 110 on which the wafer w is mounted, a top plate 130 disposed to cover the reactor block 110 and to help maintain an internal pressure of the reactor block 110, a shower head 140 which is mounted on the bottom of the top plate 130 and diffuses gases toward the wafer w, an exhaust unit (not shown) which exhausts gases from the reactor block 110, and a plasma generator 150 which generates plasma that is to be arranged between the shower head 140 and the wafer block 120.

A first supply pipeline 121 which supplies the wafer w with the first reactant gas and/inert gas and a second supply pipeline 122 which supplies the wafer w with the second reactant gas and/or inert gas are mounted in the top plate 130.

Referring to FIG. 1, the shower head 140 for diffusing a reactive gas and/or inert gas toward the wafer w which is arranged on the wafer block 120 is mounted on the bottom of the top plate 130 to be positioned in the reactor block 110 when the top plate 130 is disposed to cover the reactor block 110. The shower head 140 is formed as a single unit, rather than being formed of a plurality of plates coupled to one another by a variety of screws. An insulator 145 is interposed between the shower head 140 and the top plate 130 to insulate for insulation.

In an upper portion of the shower head 140, a first supply path 141 which is connected to the first supply pipeline 121 and a second supply path 142 which is connected to the second supply pipeline 122 are formed. The first supply pipeline 121 and the first supply path 141 are connected via a first insulating connector 121a, and the second supply pipeline 122 and the second supply path 142 are connected via a second insulating connector 122a. The first and second insulating connectors 121a and 122a prevent an electric signal generated by the plasma generator 150 from being supplied into the first and second supply lines 121 and 122, thereby reducing unexpected disturbances due to the electric signal.

Referring to FIG. 3, a plurality of first diffuse holes 1410 (denoted as white dots) and a plurality of second diffuse holes 1420 (denoted as black dots) are formed on the bottom of the shower head 140 regularly spaced to diffuse gases toward the wafer w. That is, the first diffuse holes 1410 and the second diffuse holes 1420 are spaced predetermined distances apart.

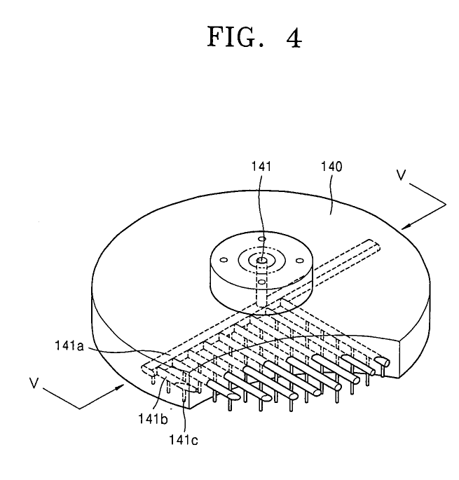

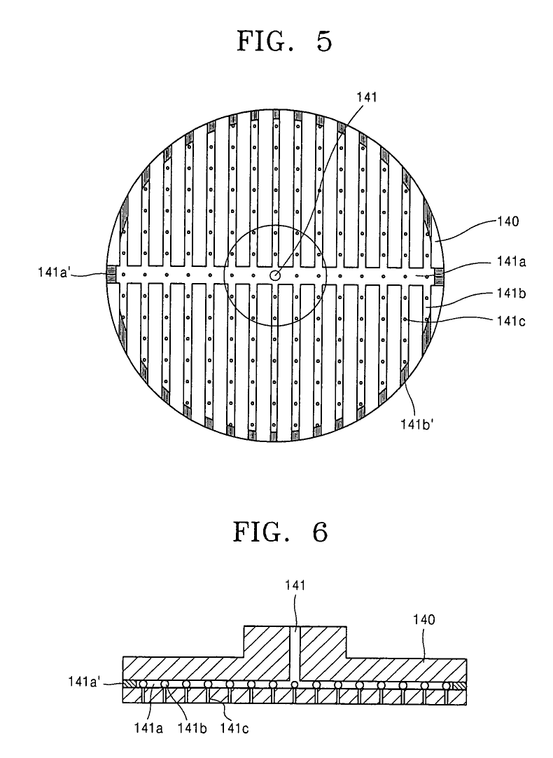

FIG. 4 is a partially cut-away perspective view of the shower head of FIG. 1,showing a first main path and the first diffuse holes 1410 connected to the first supply line 121, FIG. 5 is a cross-sectional view of the shower head taken along line V-V of FIG. 4, and FIG. 6 is a side cut-away view showing the inside of the shower head of FIG. 4.

The shower head 140, which is formed as a single unit, includes a first main path 141a extending in a horizontal direction and connected to the first supply path 141. The first main path 141a is arranged at a height d1 from the bottom of the shower head 140, as shown in FIG. 2. A plurality of first sub-paths 141b perpendicularly extend from the first main path 141a in the plane of the shower head 140. A plurality of first diffuse paths 141c extend from each of the first sub-paths 141b to the plurality of the first diffuse holes 1410 formed on the bottom of the shower head 140.

The first main path 141a is formed by drilling through the side of the shower head 140. The first sub-paths 141b are formed perpendicular to the first main path 141a by drilling through the side of the shower head 140. The first diffuse paths 141c are formed by drilling through the bottom of the shower head 140 to a height d1 of the first sub-paths 141b.

According to the present embodiment, each of the first sub-path 141b is formed perpendicularly to the first main path 141a in the horizontal direction. However, the angle between the first main path 141a and the first sub-path 141b is not limited to the right angle, but the first sub-path 141b can be formed at an angle smaller than 90° with respect to the first main path 141a in the horizontal direction.

Sealing unit for sealing both ends of the first main path 141a and both ends of the first sub-path 141b include a first main sealing member 141a′ and a first sub-sealing member 141b′. Both ends of the first main path 141a are sealed by using the first main sealing member 141a′, and both ends of each of the first sub-paths 141b are sealed by using the first sub-sealing member 141b′. By doing the above, the first main path 141a, the first sub-paths 141b, and the first diffuse paths 141c are formed in the shower head 140.

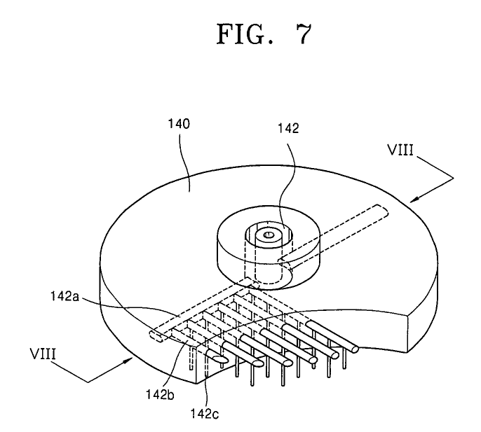

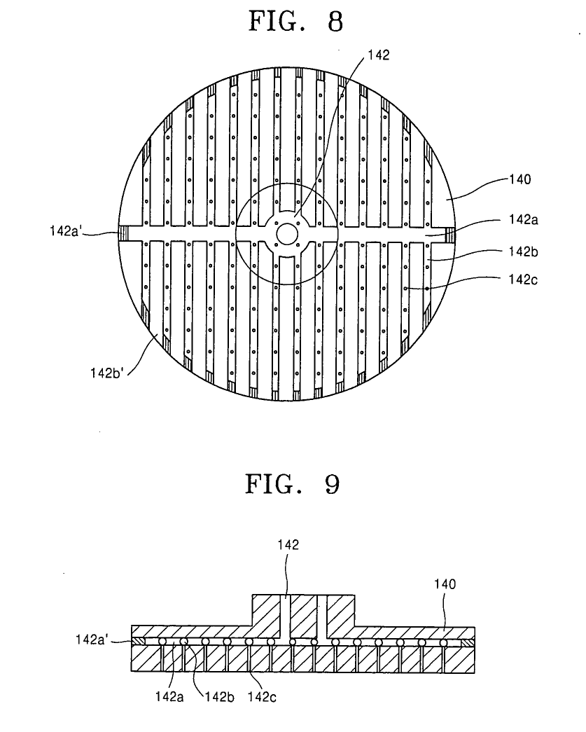

FIG. 7 is a partially cut-away perspective view of the shower head of FIG. 1, showing a second main path and the second diffuse holes 1420 connected to the second supply line 122, FIG. 8 is a cross-sectional view of the shower head taken along line VIII-VIII of FIG. 7, and FIG. 9 is a cut-away side view showing the inside of the shower head of FIG. 8.

The shower head 140 includes a second main path 142a extending in a horizontal direction and connected with the first supply path 141. The second main path 142a is arranged at a height d2 from the bottom of the shower head 140, as shown in FIG. 2. A plurality of second sub-paths 142b perpendicularly extend from the second main path 142a in the plane of the shower head 140. A plurality of second diffuse paths 142c extend from each of the second sub-paths 142b to the plurality of the first diffuse holes 1420 formed on the bottom of the shower head 140.

The second main path 142a is formed by drilling through the side of the shower head 140. The second sub-paths 142b are formed perpendicular to the second main path 142a by drilling through the side of the shower head 140. The second diffuse paths 142c are formed by drilling through the bottom of the shower head 140 to a height d2 of the second sub-paths 142b.

According to the present embodiment, each of the second sub-path 142b is formed perpendicularly to the second main path 142a in the horizontal direction. However, the angle between the second main path 142a and the second sub-path 142b is not limited to the right angle, but the second sub-path 142b can be formed at an angle smaller than 90° with respect to the second main path 142a in the horizontal direction.

Sealing unit for sealing both ends of the first main path 142a and both ends of the first sub-path 142b include a second main sealing member 142a′ and a second sub-sealing member 142b′. Both ends of the second main path 142a are sealed by using the second main sealing member 142a′, and both ends of each of the second sub-paths 142b are sealed by using the second sub-sealing member 142b′. By doing the above, the second main path 142a, the second sub-paths 142b, and the second diffuse paths 142c are formed in the shower head 140.

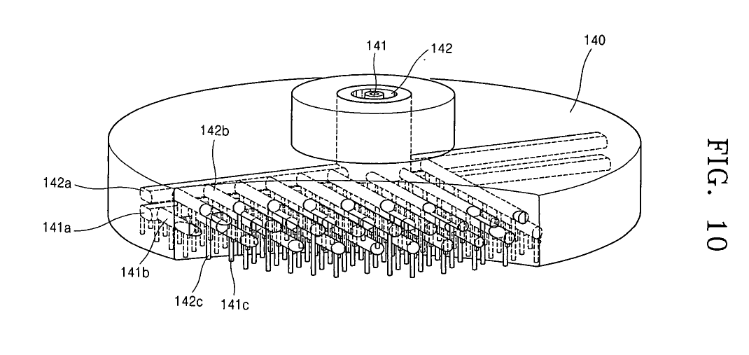

FIG. 10 is a partially cut-away perspective view of the shower head of FIG. 1, showing the first and second main paths 141a and 142a, and the first sub-path 141b and the second sub-path 141b. The first and second diffuse holes 1410 and 1420 connected to the first and second supply paths 141 and 142 . Referring to FIG. 10, the first main path 141a and the second main path 142a are formed at different heights in the shower head 140 and are sealed by using the first and second main sealing members 141a′ and 142a′, thereby completing formation of the single-body shower head.

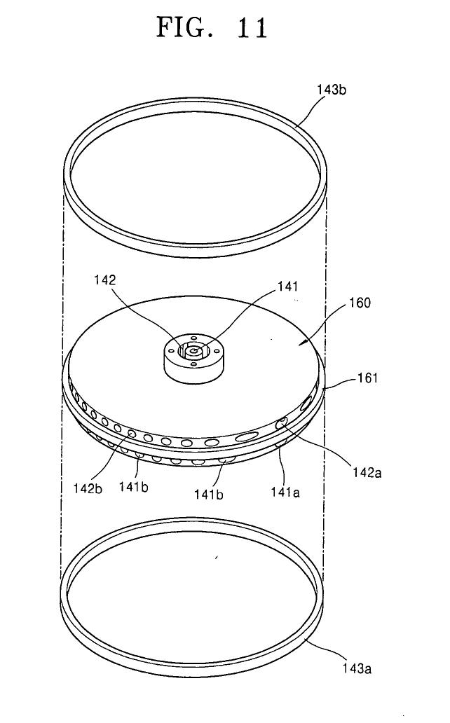

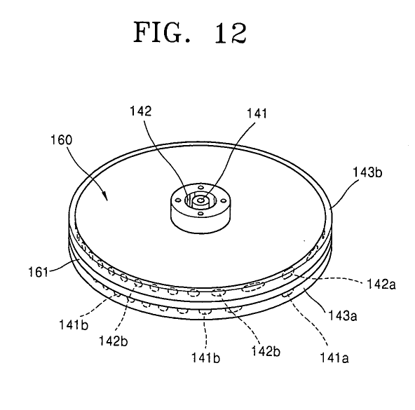

FIG. 11 is an exploded perspective view of a shower head 160 and a first and second rim members according to another embodiment of the present invention, and FIG. 12 is a perspective view of the shower head of FIG. 11, to which the first and second rim members are coupled.

Referring to FIGS. 11 and 12, the shower head 160 includes first and second supply paths 141 and 142, first and second main paths 141a and 142a, a plurality of first and second sub-paths 141b and 142b, and a plurality of first and second diffuse paths 141c and 142c (not shown) formed inside the shower head 160. In addition, a plurality of first and second diffuse holes 1410 and 1420 are formed on a bottom surface of the shower head 160, thus the shower head 160 has substantially the same structure as that of the shower head 140 of the previous embodiment. In the present embodiment, a first rim member 143a and a second rim member 143b are used as the sealing unit. However, the shower head 160 includes the first and second rim members 143a and 143b coupled on upper and lower side circumferences thereof, and a ring-shaped projection 161 having the same thickness as those of the first and second rim members 143a and 143b. The ring-shaped projection 161 is formed so that the first and second rim members 143a and 143b form a flush side portion with the shower head 160 when the first and second rim members 143a and 143b are coupled to the shower head 160.

The first and second rim members 143a and 143b may be formed of a metal, and formed as rings so as to be fitted onto the side portion of the shower head 160.

When the first rim member 143a is fitted onto the lower side circumference of the shower head 160, the open ends of the first main path 141a and the first sub-path 141b are covered. In addition, a boundary between the lower side circumference of the shower head 160 and the first rim member 143a is welded to seal the open ends of the first main path 141a and the first sub-path 141b. In this way, the first main path 141a, the first sub-path 141b, and the first diffusion path 141c are formed in the shower head 160.

In addition, when the second rim member 143b is fitted onto the upper side circumference of the shower head 160, the open ends of the second main path 142a and the second sub-path 142b are covered. In addition, a boundary between the upper side circumference of the shower head 160 and the second rim member 143b is welded to seal the open ends of the second main path 142a and the second sub-path 142b. In this way, the second main path 142a, the second sub-path 142b, and the second diffusion path 142c are formed in the shower head 160.

In the shower head according to the present invention, the first and second main paths are formed parallel to each other, however the present invention is not limited thereto. For example, the first and second main paths could be formed perpendicular to each without limitation to the present invention.

A method of fabricating the shower head having the structures according to the described embodiments of the present invention will be described as follows.

The shower head 140 of the first embodiment of the present invention includes the first supply path 141 supplying a first reaction gas and the second supply path 142 supplying a second reaction gas onto the wafer w mounted on a wafer block 120. The method of fabricating the shower head 140 includes: forming the first main path 141a penetrating a side of the shower head 140 to be connected to the first supply path 141, forming a plurality of first sub-paths 141b penetrating another side of the shower head 140 to be connected to the first main path 141a and diverging from the first main path 141a in the plane of the shower head 140, and forming a plurality of first diffuse paths 141c connecting the bottom surface of the shower head 140 to the first sub-paths 141b; forming the second main path 142a penetrating a side of the shower head 140 at a different height to that of the first main path 141a to be connected to the second supply path 142, forming a plurality of second sub-paths 142b penetrating another side of the shower head 140 to be connected to the second main path 142a and diverging from the second main path 142a in the plane of the shower head 140, and forming a plurality of second diffuse paths 142c connecting the bottom surface of the shower head 140 to the second sub-paths 142b; and sealing open ends of the first and second main paths 141a and 142a and of the first and second sub-paths 141b and 142b formed in the shower head 140.

The above sealing operation can be performed in a variety of ways, and in the present embodiment, two sealing methods will be described as examples.

Referring to FIGS. 4 through 9, the shower head can be fabricated using following first sealing method.

According to the first sealing method, the first main sealing member 141a′ is inserted into the open end of the first main path 141a to seal the open end of the first main path 141a, and the first sub-sealing member 141b′ is inserted into the open end of the first sub-path 141b to seal the open end of the first sub-path 141b. Here, the boundary between the open end of the first main path 141a and the first main sealing member 141a′ is welded to be sealed, and the boundary between the open end of the first sub-path 141b and the first sub-sealing member 141b′ is welded to be sealed.

Then, the second main sealing member 142a′ is inserted into the open end of the second main path 142a to seal the open end of the second main path 142a, and the second sub-sealing member 142b′ is inserted into the open end of the second sub-path 142b to seal the open end of the second sub-path 142b. Here, the boundary between the open end of the second main path 142a and the first main sealing member 142a′ is welded to be sealed, and the boundary between the open end of the second sub-path 142b and the second sub-sealing member 142b′ is welded to be sealed.

Referring to FIGS. 11 and 12, the shower head is fabricated using following second sealing method.

According to the second sealing method, the first rim member 143a is fitted onto the lower side circumference of the shower head 160 according to the second embodiment of the shower head according to the present invention to seal the open ends of the first main path 141a and the first sub-paths 141b. In this case, the boundary between the lower side circumference of the shower head 160 and the first rim member 143a is welded to seal the open ends of the first main path 141a and the first sub-paths 141b.

In addition, the second rim member 143b is fitted onto the upper side circumference of the shower head 160 to seal the open ends of the second main path 142a and the second sub-paths 142b. Here, the boundary between the upper side circumference of the shower head 160 and the second rim member 143b is welded to seal the open ends of the second main path 142a and the second sub-paths 142b.

When the shower head 160 is initially formed, the ring-shaped projection 161 having the same thickness as that of the first and second rim members 143a and 143b is formed so that the first and second rim members 143a and 143b are flush with the side portion of the shower head 160 when the first and second rim members 143a and 143b are coupled to the shower head 160.

The first and second main paths 141a and 142a, the first and second sub-paths 141b and 142b, and the first and second diffuse paths 141c and 142c are formed using a drilling process, however, the present invention is not limited to the drilling process. For example, the shower head can be fabricated using an ultrasonic processing method, in which fine particles lighter than the material used to form the shower head are vibrated at a very high frequency in the ultrasonic band to impact on the shower head, and thus, cracks are generated on a surface and the shower head is thus formed. In another example, the shower head of the present invention can be fabricated using an electrolytic processing method, in which the shower head is used as a positive pole and the portion to be processed is electrolysed in an alkali electrolyte.

According to the shower head and the method of fabricating the shower head according to the present invention, the shower head is formed as a single unit, and thus, the fabrication processes can be simplified. In addition, the number of areas where reaction gases can leak can be reduced.

In addition, a thin film having higher purity, superior electric characteristics, and higher step-coverage can be effectively deposited on the wafer in the thin film deposition process using a plurality of reaction gases passing through the shower head according to the present invention.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A shower head injecting gases onto a wafer mounted on a wafer block, the shower head comprising:
a first supply path supplying a first reaction gas and a second supply path supplying a second reaction gas;
a first main path connected to the first supply path in the plane of the shower head, a plurality of first sub-paths diverging from the first main path in the plane of the shower head, a plurality of first diffuse holes formed regularly spaced on a bottom surface of the shower head, and a plurality of first diffuse paths connecting the plurality of first sub-paths to the plurality of first diffuse holes;
a second main path connected to the second supply path in the plane of the shower head and not contacting the first main path, a plurality of second sub-paths diverging from the second main path in the plane of the shower head, a plurality of second diffuse holes formed regularly spaced on a bottom surface of the shower head, and a plurality of second diffuse paths connecting the plurality of second sub-paths to the plurality of second diffuse holes; and
a sealing unit sealing open ends of the first and second main paths and open ends of the first and second sub-paths formed in the shower head.

2. The shower head of claim 1, wherein the sealing unit includes a first main sealing member inserted into the open end of the first main path, and a first sub-sealing member inserted into the open end of the first sub-path.

3. The shower head of claim 2, wherein a boundary between the open end of the first main path and the first main sealing member is sealed by welding, and a boundary between the open end of the first sub-path and the first sub-sealing member is sealed by welding.

4. The shower head of claim 1, wherein the sealing unit includes a second main sealing member inserted into the open end of the second main path, and a second sub-sealing member inserted into the open end of the second sub-path.

5. The shower head of claim 4, wherein a boundary between the open end of the second main path and the second main sealing member is sealed by welding, and a boundary between the open end of the second sub-path and the second sub-sealing member is sealed by welding.

6. The shower head of claim 1, wherein the sealing unit includes a first rim member that is fitted around a lower side circumference of the shower head in order to cover the open ends of the first main path and the first sub-path.

7. The shower head of claim 6, wherein a boundary between the lower side circumference of the shower head and the first rim member is welded to seal the open ends of the first main path and the first sub-path.

8. The shower head of claim 1, wherein the sealing unit includes a second rim member fitted around an upper side circumference of the shower head in order to cover the open ends of the second main path and the second sub-path.

9. The shower head of claim 8, wherein a boundary between the upper side circumference of the shower head and the second rim member is welded to seal the open ends of the second main path and the second sub-path.

10. The shower head of claim 1, wherein the first main path and the second main path are formed in the same direction as each other, or perpendicular to each other.

11. The shower head of claim 1, wherein the first sub-path is perpendicular to the first main path.

12. The shower head of claim 1, wherein the second sub-path is perpendicular to the second main path.

13. The shower head of claim 1, wherein the first diffusion path directly connects the first sub-path to the first diffuse hole.

14. The shower head of claim 13, wherein the first diffuse path is perpendicular to the first sub-path and the first diffuse hole.

15. The shower head of claim 1, wherein the second diffusion path directly connects the second sub-path to the second diffuse hole.

16. The shower head of claim 15, wherein the second diffuse path is perpendicular to the second sub-path and the second diffuse hole.

17. A method of fabricating a shower head for injecting the gas onto a wafer mounted on a wafer block, which includes a first supply path supplying a first reaction gas and a second supply path supplying a second reaction gas, the method comprising:
forming a first main path penetrating a side of the shower head to be connected to the first supply path, a plurality of first sub-paths penetrating another side of the shower head to be connected to the first main path and diverging from the first main path in the plane of the shower head, and a plurality of first diffuse paths connecting the first sub-paths to the bottom surface of the shower head;
forming a second main path penetrating the other side of the shower head at a different height from the first main path to be connected to the second supply path, a plurality of second sub-paths penetrating another side of the shower head to be connected to the second main path and diverging from the second main path in the plane of the shower head, and a plurality of second diffuse paths connecting the second sub-paths to the bottom surface of the shower head; and
sealing open ends of the first and second main paths and open ends of the first and second sub-paths formed in the shower head.

18. The method of claim 17, wherein the sealing of the open ends further comprises sealing the open end of the first main path by inserting a first main sealing member into the open end of the first main path, and sealing the open end of the first sub-path by inserting a first sub-sealing member into the open end of the first sub-path.

19. The method of claim 18, wherein a boundary between the open end of the first main path and the first main sealing member is sealed by welding, and a boundary between the open end of the first sub-path and the first sub-sealing member is sealed by welding.

20. The method of claim 17, wherein the sealing of the open ends further comprises sealing the open end of the second main path by inserting a second main sealing member into the open end of the second main path, and sealing the open end of the second sub-path by inserting a second sub-sealing member into the open end of the second sub-path.

21. The method of claim 20, wherein a boundary between the open end of the second main path and the second main sealing member is sealed by welding, and a boundary between the open end of the second sub-path and the second sub-sealing member is sealed by welding.

22. The method of claim 17, wherein the sealing of the open ends comprises sealing the open ends of the first main path and the first sub-path by fitting a first rim member around a lower side circumference of the shower head.

23. The method of claim 22, wherein a boundary between the lower side circumference of the shower head and the first rim member is welded to seal the open ends of the first main path and the first sub-path.

24. The method of claim 17, wherein the sealing of the open ends comprises sealing the open ends of the second main path and the second sub-path by fitting a second rim member around an upper side circumference of the shower head.

25. The method of claim 24, wherein a boundary between the upper side circumference of the shower head and the second rim member is welded to seal the open ends of the second main path and the second sub-path.

26. The method of claim 17, wherein the first sub-paths are perpendicular to the first main path.

27. The method of claim 17, wherein the second sub-paths are perpendicular to the second main path.

28. The method of claim 17, wherein the first and second main paths, the first and second sub-paths, and the first and second diffuse paths are formed using a drilling method.
